(19) United States
(12) Patent Application Publication
(10) Pub. No.: US 2015/0145348 A1
(43) Pub. Date: May 28, 2015

(54) INDUCTIVE PROXIMITY SWITCH

(71) Applicant: IFM ELECTRONIC GMBH, ESSEN (DE)

(72) Inventors: Markus Preg, Waldburg (DE); Jochen Gundlach, Kressbronn (DE); Reinhard Teichmann, Essen (DE)

(73) Assignee: IFM ELECTRONICS GMBH, ESSEN (DE)

(21) Appl. No.: 14/405,540

(22) PCT Filed: Jul. 30, 2013
(86) PCT No.: PCT/EP2013/065949

§ 371 Date: Dec. 4, 2014

(30) Foreign Application Priority Data
Aug. 10, 2012 (DE) 102012214330.0
Nov. 7, 2012 (DE) 102012220275.7

(51) Int. Cl. H03K 17/95

(52) U.S. Cl. CPC H03K 17/9535
USPC 307/116

(57) ABSTRACT

Inductive A proximity switch comprising an oscillator 1 and a transmitter coil 2 for generating an alternating magnetic field, a receiving circuit 3 comprising two receiving coils 4 and 5 operating in differential connection for detecting a metallic trigger 6, wherein the receiving coils 4 and 5 are arranged such that they can be influenced differently by the trigger 6 and the induced receiving voltages cancel one another out when the trigger 6 is at a desired switching distance is provided. The coils lie in a common coil former 7 and are completely embedded in the material of the coil former. The receiving coil 4 is arranged in the outer region of the coil former 7. The coil former 7 consists of LTCC ceramic with a coefficient of thermal expansion of less than 10 ppm/K.

### CROSS-REFERENCE TO RELATED APPLICATIONS

This application claims priority to PCT Application No. PCT/EP2013/065949, having a filing date of Jul. 30, 2013, based on DE 102012214330.0 filed Aug. 10, 2012, and DE 102012220275.7 filed Nov. 7, 2012, the entire contents of which are hereby incorporated by reference.

### FIELD OF TECHNOLOGY

The following relates to an inductive proximity switch operating in a contact-free manner.

### BACKGROUND

Inductive proximity switches are used primarily in automation equipment as electronic switches operating in a contact-free manner. Inductive proximity switches operating according to the transformation principle are especially known. They are widely used in the industry and are produced in great numbers. In order to ease the mounting and exchange of the devices, they are mostly supplied with a permanently set switching distance.

An electromagnetic magnetic field that can be influenced by a target is produced with a transmitter coil. The influencing of the magnetic field by the target is electronically monitored and is emitted as a binary switching signal via a switching stage.

Such switches are produced and marketed in numerous designs including by the applicant. Needed to realize the transformative principle are at least one transmitter coil and one inductive receiver coil coupled to the transmitter coil. The essential measured value is the transformative coupling factor between the two coils. The transformative coupling factor of both coils is influenced by the target. The degree of influence affects the signal at the receiver coil. Depending on the properties of the target, phase displacements can also arise which can contribute to the measurement result in different ways according to the evaluation procedure.

Upon the intrusion of a target, a switching lug or a control lug into the monitoring area of the proximity switch, the transformative coupling factor of the transformer formed from the two coils is influenced, as already mentioned, and depending on the concrete design of the proximity switch, either a switching signal is activated when the signal exceeds a certain value at the transmitter coil, or at the receiver coil or when it falls below this value.

Since the measurement mostly occurs based on signal amplitude, the high frequency signal is rectified, smoothed and sent to a comparator. It can also be digitalized and processed in a micro-controller.

Both the control of the transmitter coil and the evaluation of the influence of the target can thereby occur in different ways. In many cases the transmitter coil is a component part of an oscillator influenced by the target. There are, however, also transmitter coils that are externally controlled by a high frequency generator. The reciprocal effect with the target is in any event limited to the induction field. It therefore declines with triple the power of the switching distance. In order to be able to verify even smaller reciprocal effects with the target, it is advantageous to compensate the signal in the uninfluenced state and only evaluate the changes caused by the target. To that end two receiver coils are preferably operated in a differential circuit. The construction is so selected that one of the two coils is influenced more strongly by the target than the other. By means of a null balance in the non-influenced state, a very sensitive differential coil arrangement is obtained. This is so balanced that the signals of both receiver coils mutually cancel each other out in the uninfluenced or in a specified state. The better this balance succeeds, the higher one can amplify the sensor signal without resulting in an over-control of the amplifier.

Since the magnetic field and thus the reciprocal effect of the coil arrangement with the metal target rapidly diminishes with increasing range, temperature influences, in particular location changes of the copper coils, but also the temperature variations in the other involved materials and component elements, can cause signal changes which lie in the same order of magnitude as the expected sensor signal. Thus greater switching distances are only attainable, when the temperature dependency of the arrangement can be compensated for across the entire working temperature range. This equilibrium can not only be disturbed by the casting of the devices during manufacture but also by the assembly situation at the place of installation.

A factory-adjustment of the differential coil arrangement during manufacture can only eliminate the problem for a narrow temperature range.

In order to increase sensitivity and simultaneously suppress undesirable influences, it is proposed in DE4102452A1 to operate two receiver coils in a direct differential circuit. One coil thereby serves as actual receiving coil and the other as a reference coil that is less influenced by the target, and ideally uninfluenced by it. The two receiver coils here lie in a feedback branch of a Meissner oscillator. Evaluated is the oscillator amplitude. The switching distance is achieved when, due to the reciprocal interaction with a target, the differential alternating voltages of both coils is cancelled. In this case the oscillator changes its oscillation state abruptly. The arrangement is therefore very sensitive but is also correspondingly interference-prone.

It is therefore proposed in DE10012830A1 that the signal to be evaluated is acted upon by the oscillator frequency, in order to filter out interference signals. It is furthermore proposed to subtract the remaining offset of the measured signal by the addition of the inverted oscillator signal. Disadvantageous is the limitation of the maximum attainable switching frequency by the stalling and renewed buildup of oscillation by the oscillator.

The differential coil arrangement is, as shown in DE10012830A1, constructed generally symmetrically, i.e. the reference coil has the same diameter and is also at the same distance to the transmitter coil as to the actual receiver coil. Only thus can the thermal sensitivity required for highly sensitive devices be achieved. With different distances to the transmitter coil, the inductive coupling factors are functions of the temperature, due to the thermal expansion coefficients of the carrier materials, which can be complicated to correct. As stated above, even the changes in position of the copper coils have to be taken into account, because of their thermal expansion.

The symmetrical differential coil arrangement is however problematic as well, because the decoupling of the reference coil only succeeds to an unsatisfactory extent. The reference coil is only insufficiently shielded from the target by the transmitter coil primarily because of its diameter. The residual inductive coupling of the reference coil to the target necessarily influences the measured signal.

For this reason, an arrangement with two transformers (coil pairs) decoupled from each other is proposed in DE10350733B4. Thus the influence of the target on the reference coil is largely eliminated. However a second transmitter coil is now required. Disadvantageous thereby is the material cost for the additional transmitter coil and the space requirement for the two coil pairs decoupled from each other, i.e., offset with respect to each other preferably by 90°.

### SUMMARY

An aspect relates to a compact, temperature-sensitive, inductive proximity switch with long-term stability.

The aspect is inventively attained with the properties as set forth hereinafter. Advantageous embodiments of the invention are provided.

The essential inventive idea is to house all three coils of the differential coil arrangement in a monolithic coil body block with high dimensional stability and low thermal expansion coefficients. The coil body block advantageously consists of an LTCC glass ceramic, Low Temperature Co-fired Ceramic, which exhibits a heat expansion coefficient of 6-8 ppm/K and the desired high dimensional stability. The known printed circuit board coils based on the FR4 circuit board material do not achieve the necessary thermal stability. The inventive sensor coil constructionism therefore designed as multi-layer ceramic using the LTCC technique. The coils are thereby printed layer by layer onto the unfired (green) ceramic using serigraphy. The conductor paths preferably consist of copper but can also be made of silver. After the stacking and pressing, the multi-layer construction is fired in a process furnace at about 900° C. If needed, capacitors, shielding grids and/or a metal structure can be emplaced in the ceramic body for pre-attenuation of the reference coil. The thermal coupling of the coils is also improved by the inventive construction. One advantage of the LTCC ceramics over other ceramics is the low dielectric losses. The permittivity of the ceramics lies at about 7.

### BRIEF DESCRIPTION

Some of the embodiments will be described in detail, with reference to the following figures, wherein like designations denote like members, wherein:

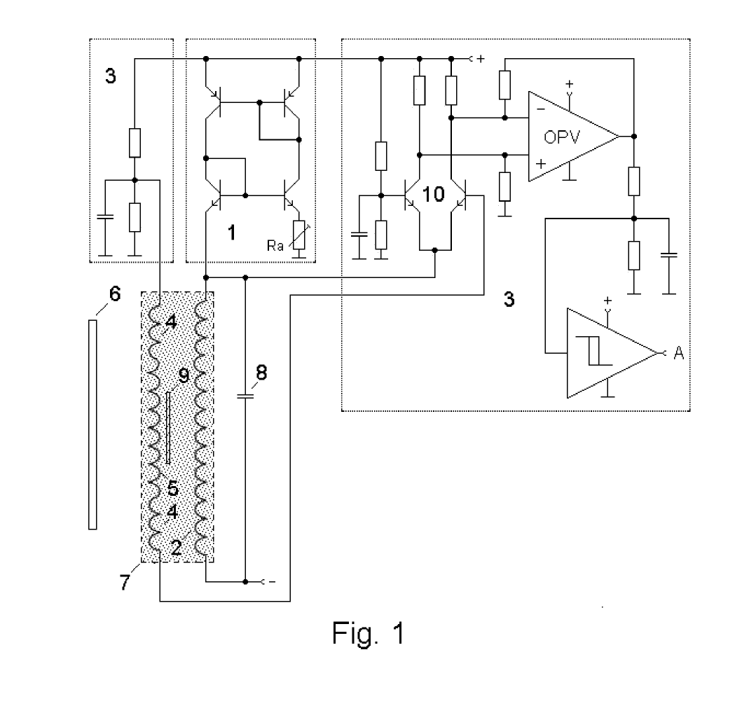

FIG. 1: An inventive proximity switch with a current mirror oscillator;

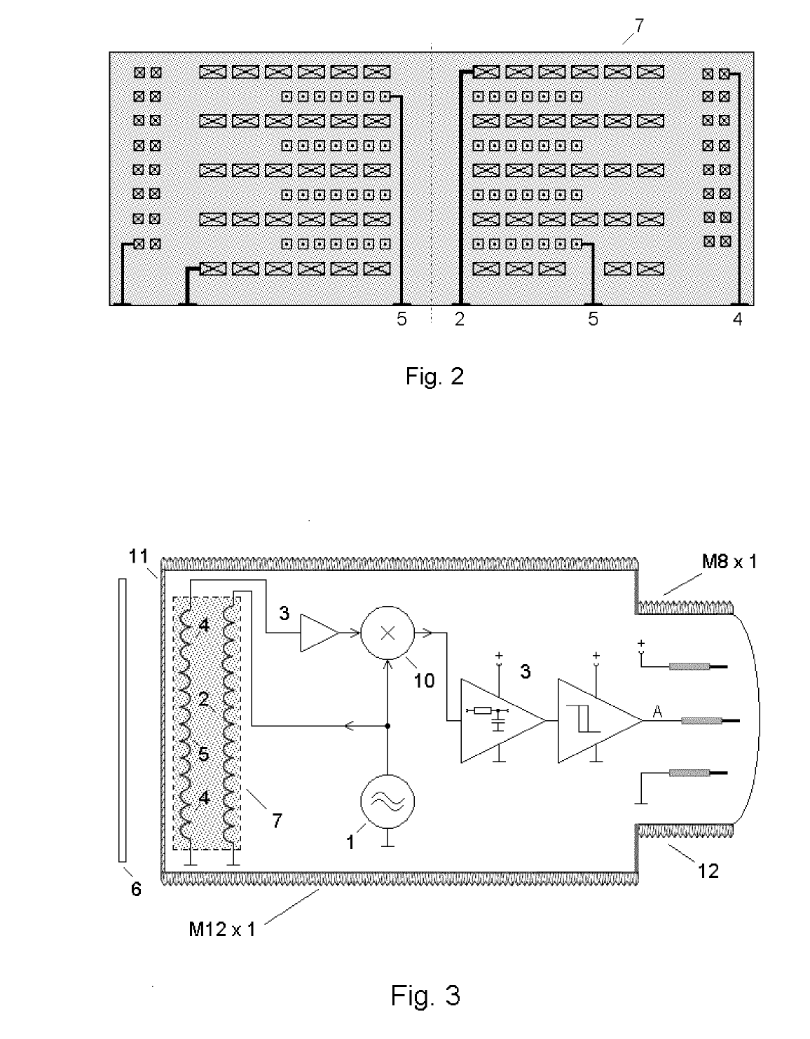

FIG. 2: An inventive coil body with the receiver coil at the edge; and

FIG. 3: A longitudinal cut of an inventive cylindrical proximity switch.

### DETAILED DESCRIPTION

FIG. 1 shows the essential switch elements of the inventive inductive proximity switch in an extremely simplified depiction. The generator 1 is constructed as a current mirror oscillator. Advantageous is the high amplification which results in a rapid oscillation build-up and impedes the oscillation outline with strong damping. The amplitude of the oscillator signal can be compensated with the resistance Ra. Another advantage consists of the fact that this circuit gets by without a center tap of the oscillator coil simultaneously serving as the transmitter coil 2.

The anti-serially connected receiver coils 4 and 5 are connected to a trans-conductance mixer 10 whose emitter branch is acted upon by the oscillator signal. This arrangement, in particular the coupling of the transmitter coil 2 with the trans-conductance mixer 10, is depicted in a greatly simplified manner. A Gilbert cell is definitely better suited here. All three coils are enclosed in a monolithic ceramic block, the coil body 7. The construction is so chosen that the differential signal of the two receiver coils 4 and 5 amounts to zero in the uninfluenced state. The low heat expansion coefficient of the coil body material, typically consisting of 8 ppm/K, provides the necessary thermal stability of the arrangement.

The coil body 7 advantageously consists of LTCC ceramic and contains in the embodiment shown the oscillation circuit capacitor 8 in addition to the three coils and a pre-damping surface 9 for the reference coil 5.

The pre-damping surface 9 can also be structured. It serves for defined pre-damping of the reference coil 5 which is ideally not influenced by the target 6. In this way the influence of the assembly location on the switching distance of the proximity switch can also be reduced.

The differential signal of the receiver coils 4 and 5 is sent to the trans-conductance mixer 10 which operates as an analog-multiplier. It multiplies the reception signal with the oscillator signal, which here also serves as transmitter signal.

Interferences are largely screened out by an in-phase evaluation. However phase displacements caused by the target 6 also have some influence on the results.

The pulsating direct voltage signal originating at the multiplier 10 is smoothed and sent to a trigger or comparator, which compares the signal with a threshold value, and depending on the damping state of the coil arrangement, produces a binary switching signal. The evaluation circuit 3 can inventively also contain an integrator or a correlator in place of the multiplier 10 which is advantageously deposited as software in a micro-controller. The switching output A can naturally exhibit the functions customary with proximity switches, such as electronic fuse and/or excess voltage protection.

The invention is naturally not limited to the arrangement shown. The inventive ceramic coil can also be a component part of a three point oscillator. It must also not necessarily belong to a frequency determining resonant circuit but can instead be acted upon by sinus, triangular or rectangular impulses of any desired frequency or impulse shape produced by a high frequency generator 1.

FIG. 2 shows a ceramic coil 7 according to embodiments of the invention. Each ceramic layer contains one coil layer which however can also belong to different coils which are connected to each other via non-depicted interlayer connections. The external coil contacts are only schematically depicted. The number of coil layers is not representative.

In order to keep the transmission current as low as possible, the transmitter coil features more windings on its contacts 2 than the receiver coil 4 and the reference coil 5. All three coils lie approximately in a common center plane. The receiver coil 4 is positioned because of the better contact to the target 6 on the edge of the coil body 7 at a certain distance to the transmitter coil 2. The resonant circuit capacitor 8 is advantageously positioned on the back side of the transmitter coil 2. The pre-damping surface 9 is also not depicted. It can inventively lie on both sides of the reference coil 5, namely also on the side of the reference coil 5 facing the target. All three coils are in contact across the back side of the coil body 7.

FIG. 3 shows a longitudinal cut of an inventive proximity switch in a cylindrical configuration. The circuit elements shown in FIG. 1 are depicted here in a very simplified manner.

The front area 11 can consist of metal, preferably stainless steel, but can also consist of plastic or ceramic. Its edge area is used as completely as possible as a receiving surface and therefore is filled by the receiver coil 4. The device features a plug 12 and a threaded connection M8 x 1 and is provided with an external thread M12 x 1 to facilitate assembly. The other circuit elements have already been explained. The evaluation circuit 3 consists here of a preamplifier, a multiplier 10, an integrator and a Schmitt trigger to produce the binary switching signal.

The current supply and the switching stage that is generally equipped with a current limiter or a short-circuit protection are not depicted.

The invention embodiments of the invention relates to an inductive proximity switch with an oscillator 1 and a transmitter coil 2 for producing a magnetic alternating field, a receiving circuit 3 with two receiver coils 4 and 5, operated in a differential circuit, for detecting a target 6 penetrating into the magnetic alternating field, wherein the receiver coils 4 and 5 are so positioned and constructed that they can be influenced differently by the target 6, and the induced receiving voltages mutually cancel each other out at a desired (switching) distance of the target 6. That can also be the case in the absence of the target 6. All three coils are housed in a common coil body 7 and are completely embedded in the coil body material. It has proven advantageous to position the receiving coil 4 on the edge and the reference coil 5 in the center of the common coil body 7.

The coil body material exhibits a heat expansion coefficient smaller than 10 ppm/K. Typical is 8 ppm/K, The permittivity εᵣₑₗₐₜᵢᵥₑ of the coil body material is less than 7. The typical value is 5.8. The coil body 7 is advantageously comprised of a multi-layer ceramic body of LTCC or HTCC ceramic, wherein the abbreviation HTCC stands for “High Temperature Co-fired Ceramics”. The two receiving coils 4 and 5 can be interlaced with the windings of the transmitter coil 2, i.e., the coils can mutually penetrate each other.

The distances between the receiver coils 4 and 5 and the transmitter coil 2 and also their diameters can be different. The reference coil 5 needs a higher winding count than the receiver coil 4 because of its smaller diameter. Since the reference coil 5 exhibits a smaller diameter and is positioned in the region of the proximity switch near the axis, it is definitely less influenced by the target than the actual receiver coil 4.

In another advantageous embodiment of the invention, the reference coil 5 is completely enclosed by the transmitter coil 2. Thus the reference coil 5 is better decoupled from the target 6 and the sensitivity of the arrangement is increased. This arrangement has a positive effect on the temperature variations. The receiver coil 4 and the reference coil 5 advantageously exhibit the same transformer coupling factor to the transmitter coil 2. In many cases the same inductive resistance is also an advantage.

The heat conductance of the coil body material amounts to at least 3 W/(m*K). A capacitor 8 (resonant circuit capacitor) and a pre-damping surface 9 for pre-damping the reference coil 5 can be embedded in the coil body 7. The receiver coil 2 can be positioned at a distance to the transmitter coil 2.

### LIST OF REFERENCE CHARACTERS

1 Oscillator, high frequency generator

2 Transmitter coil

3 Receiver circuit

4 Receiver coil (1^{St} receiver coil)

5 Reference coil (2^{nd} receiver coil)

6 Target

7 Coil body with transmitter coil 2 and the receiver coils 4 and 5

8 Capacitor, resonant circuit capacitor

9 Pre-damping surface

10 Multiplier

11 Front area

12 Plug with threaded connection M8 x 1

A Switching output

Ub Operating voltage

Ra Adjustment resistance

1. An inductive proximity switch with an oscillator and a transmitter coil to produce a magnetic alternating field, a receiving circuit with two receiver coils operated in a differential circuit for the purpose of detecting a target penetrating the magnetic alternating field, wherein the receiver coils are so positioned and constructed that their signals cancel each other out at a certain distance to the target, wherein all three coils are housed in a common coil body, are completely embedded in the coil body material and surrounded by it, wherein the first receiver coil is positioned in the edge area of the common coil body.

2. The inductive proximity switch according to claim 1, wherein the heat expansion coefficient of the coil body material is smaller than 10 ppm/K.

3. The inductive proximity switch according to claim 1 wherein the coil body is constructed as a multi-layer LTCC or HTCC ceramic.

4. The inductive proximity switch according to claim 1, wherein both receiver coils exhibit the same transformer coupling factor to the transmitter coil.

5. The inductive proximity switch according to claim 1, wherein a capacitor is embedded in the coil body.

6. The inductive proximity switch according to claim 1, wherein the coil body features a metallic pre-damping surface for electric pre-damping of the second receiver coil.

7. The inductive proximity switch according to claim 1, wherein the reference coil is positioned in the region of the coil axis and the receiver coil at a distance to the transmitter coil.

8. The inductive proximity switch according to claim 2, wherein the coil body is constructed as a multi-layer LTCC or HTCC ceramic.

9. The inductive proximity switch according to claim 2, wherein both receiver coils exhibit the same transformer coupling factor to the transmitter coil.

10. The inductive proximity switch according to claim 3, wherein both receiver coils exhibit the same transformer coupling factor to the transmitter coil.

11. The inductive proximity switch according to claim 2, wherein a capacitor is embedded in the coil body.

12. The inductive proximity switch according to claim 3, wherein a capacitor is embedded in the coil body.

13. The inductive proximity switch according to claim 4, wherein a capacitor is embedded in the coil body.

14. The inductive proximity switch according to claim 1, wherein the coil body features a metallic pre-damping surface for electric pre-damping of the second receiver coil.

15. The inductive proximity switch according to claim 2, wherein the coil body features a metallic pre-damping surface for electric pre-damping of the second receiver coil.

16. The inductive proximity switch according to claim 3, wherein the coil body features a metallic pre-damping surface for electric pre-damping of the second receiver coil.

17. The inductive proximity switch according to claim 4, wherein the coil body features a metallic pre-damping surface for electric pre-damping of the second receiver coil.

18. The inductive proximity switch according to claim 5, wherein the coil body features a metallic pre-damping surface for electric pre-damping of the second receiver coil.

19. The inductive proximity switch according to claim 2, wherein the reference coil is positioned in the region of the coil axis and the receiver coil at a distance to the transmitter coil.

20. The inductive proximity switch according to claim 3, wherein the reference coil is positioned in the region of the coil axis and the receiver coil at a distance to the transmitter coil.
